(19) United States
(12) Patent Application Publication
(10) Pub. No.: US 2014/0076774 A1
(43) Pub. Date: Mar. 20, 2014

(54) Automated Wafer Container with Equipment Interface

(71) Applicant: Kurt F. Kaashoek, SCOTTSDALE, AZ (US)

(72) Inventor: Kurt F. Kaashoek, SCOTTSDALE, AZ (US)

(21) Appl. No.: 14/030,051

(22) Filed: Sep. 18, 2013

Related U.S. Application Data
(60) Provisional application No. 61/702,545, filed on Sep. 18, 2012.

(51) Int. Cl. H01L 21/673

(52) U.S. Cl. CPC H01L 21/67373
USPC 206/711; 206/710

(57) ABSTRACT

An improved wafer container is provided for use with automated equipment. The container includes a top lid that engages with a bottom base to form a housing having an inner cavity for storing semiconductor wafers. The lid includes a handling member that interfaces with automated equipment for engaging the lid with the base and removing the lid from the base. The container includes latches that can be actuated between a locked position and an unlocked position by automated equipment. The container can hold multiple stacked wafer separator rings, each of which has automation tabs extending outwardly from the ring outer rim. The automation tabs allow for automated equipment to transfer the wafer separators rings between the container and a staging area.

### RELATED APPLICATION DATA

This application is based on and claims the benefit of U.S. Provisional Patent Application No. 61/702,545 filed on Sep. 18, 2012, the disclosure of which is incorporated herein in its entirety by this reference.

### BACKGROUND

Semiconductor wafers increase in cost and fragility as they move through the fabrication process. During and after the fabrication process wafers are shipped to other fabrication and assembly/test sites that are often located thousands of miles away. Historically semiconductor manufacturer's reused incoming prime wafer shipper containers to ship finished wafers to other sites because the cost of the shipper container was perceived to be free since it was included in the cost of the incoming silicon. Despite the perception that these incoming wafer shippers were free, the industry now understands that these containers are not designed for finished wafers and suffer yield loss (around 0.5%) plus a significant cost per wafer shipping penalty.

A superior method of packing and shipping costly, fragile finished wafers is to use a coin stack format horizontal wafer container where wafers are stacked on top of each other with very clean conductive interleaves typically made from polyethylene film or ring separators typically molded from polypropylene separate each wafer. Suspension components—either injection molded forms or clean closed cell polyethylene foam cushions—are placed on each end of the stack to cushion the wafer from external shocks. Coin stack format wafer shippers have virtually eliminated wafer damage through the shipping process and reduced shipping costs by as much as 80%.

Despite providing outstanding wafer protection and shipping cost reduction, existing coin stack format wafer containers have a significant shortcoming—they are designed primarily for manual handling. The opening and closing latches require manual dexterity of the human hand and are not compatible with automation. Once the operator removes the lid they place the container manually on a process tool. Before starting the process, the operator typically places the wafer suspension components in the container. Upon completion of the packing or unpacking process, the operator manually adds additional suspension components, replaces the lid and removes the container from the process tool. Also, existing ring separators have features that are not compatible with automated handling. In process, the wafer height is not consistent but instead is a function of the wafer thickness. With existing ring separators, the wafer surface sits below the ring edge, which prohibits direct pick and place transfer with vacuum end effectors technology.

Lead edge wafer fabrication factories, however, are fully automated facilities that in many cases run “lights out” with no operators present. As process technologies continue to shrink the need for increased levels of automation and minimal operator intervention only increases and the next wafer size transition will make operator intervention in the process prohibitive.

It is an object of the invention, therefore, to provide a new wafer container design and equipment interface that can function properly in a fully automated wafer fabrication environment without the need of operator intervention.

It is also an object to provide a rugged latching mechanism that is easily opened and closed with automatic actuators.

Another object of the invention is to provide a ring separator that provides full perimeter protection to the wafer and allows the wafer surface to be accessed by standard vacuum end effectors designs.

Yet another object of the invention is to provide an improved wafer container lid design with robotic flange to interface with fabrication automation and integrated suspension components that do not require manual placement.

Still another object of the invention is to provide an equipment interface that can accept the container from standard fabrication automation equipment, open, remove, and replace the container lid, and remove and replace the container contents automatically.

Additional objects and advantages of the invention will be set forth in the description that follows, and in part will be apparent from the description, or may be learned by practice of the invention. The objects and advantages of the invention may be realized and obtained by means of the instrumentalities and combinations pointed out in this specification.

### SUMMARY OF THE INVENTION

To achieve the foregoing objects, and in accordance with the purposes of the invention as embodied and broadly described in this document, there is provided an improved wafer container for use with automated equipment. The container includes a top lid adapted for engagement with a bottom base to form a housing having an inner cavity for storing at least one semiconductor wafer. The lid includes a handling member adapted to interface with automated equipment for placing the lid into engagement with the base and removing the lid from engagement with the base. The base includes a latch member and the lid includes a latch retainer portion adapted for receiving the latch member when the lid is in engagement with the base. When the lid is in engagement with the base and the latch member is received by the lid latch retainer portion, the latch member can be actuated between a locked position and an unlocked position by automated equipment.

In one advantageous embodiment, the latch member includes a tab adapted to protrude through a latch hole disposed in the lid when the lid is engagement with the base. The tab can be rotated between the locked position and the unlocked position when it protrudes through the latch hole. The tab is disposed within a recess in the lid when the tab is in engagement with the base and the tab protrudes through the latch hole. The lid recess can be sized to allow movement of the latch between the locked position and the unlocked position by hand. The latch member includes a generally cylindrical body that is rotatable between the locked position and the unlocked position.

According to other features of the invention, the housing inner cavity can be adapted for holding a plurality of wafer separator rings in a stacked configuration. Each of the one or more wafer separator rings can be adapted for placement on the base by automated equipment when the lid is not in engagement with the base. The lid handling member can include a flange adapted to interface with equipment for automatic removal and replacement of the lid. The base can include a latch enclosure and the latch member cylindrical body can be disposed within the latch enclosure with a bottom portion of the cylindrical body and can be accessible at the bottom of the base to automation equipment for rotating the latch between the closed position and the open position. A wafer suspension component can be removably secured to the inside top of the lid.

In this configuration, the latch can securely hold the base and lid of the container together and can be automatically opened and closed by a keyed actuator or by hand via the tab from the top of the container. The tabs can be slightly recessed from the surface of the lid to prevent damage during shipment or inadvertent operation. The lid interface can include small projections that prevent the tabs from over-rotating and can hold them securely in the closed position. The cylindrical latch body can have flats opposite each other that act as cams to ensure that the latch stays closed during shipment. A latch retainer clip can secure the latch in place, yet allow for removal and replacement of the latch for maintenance or cleaning of the container. The latch retainer clip can include tabs with flat surfaces that fit tight against the latch body to hold it in the closed position and still allow it to rotate.

The wafer container can include an improved lid with integrated suspension components and a top flange that is compatible with standard semiconductor automated handling equipment. The lid can have a plurality of small bosses or other retention features disposed around the perimeter of wafer containment walls, which can hold a suspension components (such as a molded compression rings or closed cell polyethylene cushions). The top of the lid can include a robotic flange that emulates the flange on the existing industry standard wafer shipping and process carriers and is compatible with existing wafer factory automation. The top flange can either be molded into the lid or replaceable.

In another embodiment, a wafer container for use with automated equipment according to the invention includes a top lid adapted for engagement with a bottom base to form a housing having an inner cavity for storing at least one semiconductor wafer having a diameter. At least two wafer separator rings are disposed inside the inner cavity. Each of the separator rings includes an outer rim having an outer diameter that is larger than the semiconductor wafer diameter and at least one automation tab extending outwardly from the outer rim.

According to other features of the invention, at least two of the wafer separator rings are configured so that when they are disposed inside the inner cavity in a stacked arrangement they define a pocket between the wafer separator rings for closely holding a peripheral portion of the semiconductor wafer. The stacked wafer separator rings have interlocking mating surfaces that are chamfered. The wafer separator ring automation tab defines a generally planar top surface that is offset below a top surface of the outer rim. The outer rim includes a recessed slot adjacent the automation tab top surface. The depth of the outer rim recessed slot is below the equator of a semiconductor wafer positioned in the wafer separator ring. The outer rim includes a projection opposing the recessed slot and that has dimensions that correspond with the depth and width of the recessed slot.

The wafer container includes an improved wafer separator ring that provides complete perimeter protection for the wafer, an automation slot to expose the wafer surface and allow it to be handled using a vacuum end effectors, an automation tab to allow a full container of rings to be transferred from the container to a staging area, and standard wafer spacing regardless of wafer thickness. The outer perimeter of the ring will be greater than the wafer diameter and the wafer will sit in a recess to provide full perimeter protection.

One embodiment of a wafer separator ring according to the present invention includes an outer rim having an upper portion that has a generally planar top surface and an outer diameter that is greater than the diameter of a semiconductor wafer. The outer rim also has an opposing lower portion having a bottom surface and an outer diameter that is greater than the top portion outer diameter. The ring has a first top inner shoulder disposed inward of the rim upper portion and recessed from the rim top surface, wherein the first top inner shoulder has an outer diameter that is slightly larger than the wafer diameter and has a perimeter shape that corresponds to the shape of the wafer perimeter. A second top inner shoulder is disposed inward of and recessed from the first top inner shoulder. A first bottom inner shoulder is disposed inward of the rim lower portion and recessed from the rim bottom surface, wherein the first bottom inner shoulder has an outer diameter that is slightly larger than the rim upper portion outer diameter. A second bottom inner shoulder is disposed inward of and recessed from the first bottom inward shoulder. The second bottom inner shoulder has a diameter that is slightly larger than the wafer diameter. The rim the lower portion has in inner diameter at the first bottom inner shoulder that corresponds to the perimeter. The second top recessed inner shoulder can define a generally planar vacuum pickup surface having sufficient width for engaging a vacuum cup of automated handling equipment.

According to another features of the wafer separator ring, the first top inner shoulder can have a recess depth that is greater than half the thickness of the peripheral portion of the wafer. The second bottom inner shoulder has a recess depth that is less than half the thickness of the peripheral portion of the wafer. The sum of the first top inner shoulder recess depth and the second bottom inner shoulder recess depth is greater than the thickness of the peripheral portion of the wafer.

An equipment interface for the wafer container can provide fully automated operation. The interface can include an automated drawer to accept the wafer carrier from standard factory automated equipment. The drawer can include guide pins to locate the container and keyed actuators to open and close the container latches. The interface can include an overhead cover lifting mechanism to grip the lid flange and remove or replace the lid from the container. The interface also can include an end effectors that can transfer wafer separators rings between the container and a staging area either individually or as a complete stack of a plurality of rings (e.g., twenty five rings).

### BRIEF DESCRIPTION OF THE DRAWINGS

The accompanying drawings, which are incorporated in and constitute a part of the specification, illustrate the presently preferred embodiments and methods of the invention and, together with the general description given above and the detailed description of the preferred embodiments and methods given below, serve to explain the principles of the invention.

FIG. 1 shows a perspective exploded view of one embodiment of an automated wafer container according to the present invention, with a plurality of wafer rings disposed between the wafer container lid and base.

FIG. 2 shows a perspective view of the automated latch in the base of the wafer container of FIG. 1, with the automated latch in the open position.

FIG. 3 shows a top view of the automated latch of FIG. 2 with the wafer container lid in place and with the automated latch in the locked position.

FIG. 4 shows a section view of the automated latch of FIG. 2 in a closed position with locking tabs engaged.

FIG. 5 is a detailed bottom view of the automated latch of FIG. 4, showing the keyed interface of the automated latch at the bottom of base of the wafer container.

FIG. 6 is a detailed perspective view of one embodiment of an automated latch actuator for use with the automated wafer container of FIG. 1, which shows a keyed interface protruding from an equipment wafer carrier interface plate.

FIG. 7 is a detailed front cross-section view of a portion of the lid of the wafer container of FIG. 1, showing an integrated suspension component.

FIG. 8 is a detailed bottom perspective view of the integrated suspension component retention feature built into the wafer container lid of FIG. 7.

FIG. 9 shows a top perspective view of the automated wafer ring.

FIG. 10 shows a top perspective detailed view of the ring automation tab with automation slot, recessed wafer pocket, and a second recessed vacuum pick up surface.

FIG. 11 shows a bottom perspective detailed view of the ring automation tab with locking feature and recessed wafer pocket.

FIG. 12 shows a section view of a two wafer ring stack with wafers.

FIG. 13 shows a section view of a two wafer ring stack with wafers at the automation tab.

FIG. 14 shows a perspective view of two wafer ring automation tabs stacked with the automation slot and bottom locking feature and a wafer in the top ring.

FIG. 15 shows a perspective view of the equipment interface for the automated wafer carrier system with the automated lid removal system, wafer carrier base on automated sliding shelf and automated wafer ring in the ring handling system.

FIG. 16 shows a perspective view of the ring handling end effectors with a full set of wafer separator rings.

FIG. 17 shows a side view of the ring handling end effectors gripper with a full set of twenty five rings held by the ring automation tab.

FIG. 18 shows a side view of the ring handling end effectors with the vacuum cups holding a single ring and the ring gripper arms retracted.

### DETAILED DESCRIPTION

Referring to the drawings, wherein like reference numbers are used herein to designate like elements throughout the various views, preferred embodiments of the present invention are illustrated and described. As will be understood by one of ordinary skill in the art, the figures are not necessarily drawn to scale, and in some instances the drawings have been exaggerated and/or simplified in places for illustrative purposes only. One of ordinary skill in the art will appreciate the many applications and variations of the present invention in light of the following description of the preferred embodiments of the present invention. The preferred embodiments discussed herein are illustrative examples of the present invention and do not limit the scope of the invention to the preferred embodiments described.

Referring to FIGS. 1 and 7, a wafer container 10 according to the present invention includes a wafer container lid 100 and base 200, which mate in a clam shell arrangement. The wafer container lid 100 and base 200 can house a plurality of semiconductor wafers 21 and ring separators 20. As shown in FIG. 1, a plurality of semiconductor wafers 21 are disposed between the wafer container lid 100 and base 200. The semiconductor wafers 21 are interleaved between the ring separators 20. The wafer container base 200 includes a generally planar rectangular bottom section with wall structures 209 that extend perpendicular and in a circular orientation from the bottom section for rigidity. The wafer container lid 100 has a generally planar rectangular top section with an inner wail 106 (see FIG. 7) that extends perpendicularly from the inside surface of the lid 100 in a circular orientation. The base inner walls 209 include an automation slot 204 to allow access to the plurality of wafers, to provide alignment of an automation tab 23 on each ring separator 20 and to prevent damage and shifting of the wafers during shipment and handling. A suspension component 201 can be placed at the bottom of the base inner walls 209 to support the plurality of wafers 21 and ring separators 20.

Referring to FIGS. 1-3, the base 200 includes a plurality of automated latch enclosures 206, each of which encloses an automated latch 214 with a latch tab 203 projecting from the top of the latch enclosure 206. When the lid 100 is placed on the base 200 (see FIG. 3), the latch tab 203 protrudes through a latch slot 101 and into a latch lid recess 103 at the corners of the lid 100. The latch tab 203 secures the lid 100 to the base 100 when the latch is turned 90 degrees, either by manually accessing the latch tab 203 in the latch lid recess 103 or by automatically turning the latch 214 with a keyed actuator through the base 200. The lid 100 includes a top robotic flange 102 that provides a standard interface for automated equipment (such as equipment that complies with SEMI M13 or other applicable SEMI Standards) to transport the wafer container 10 through the factory and to automatically remove and replace the lid 100. The robotic flange 102 can either be molded into the lid 100 or mechanically secured to the lid 100 in a way that can be removed for shipment.

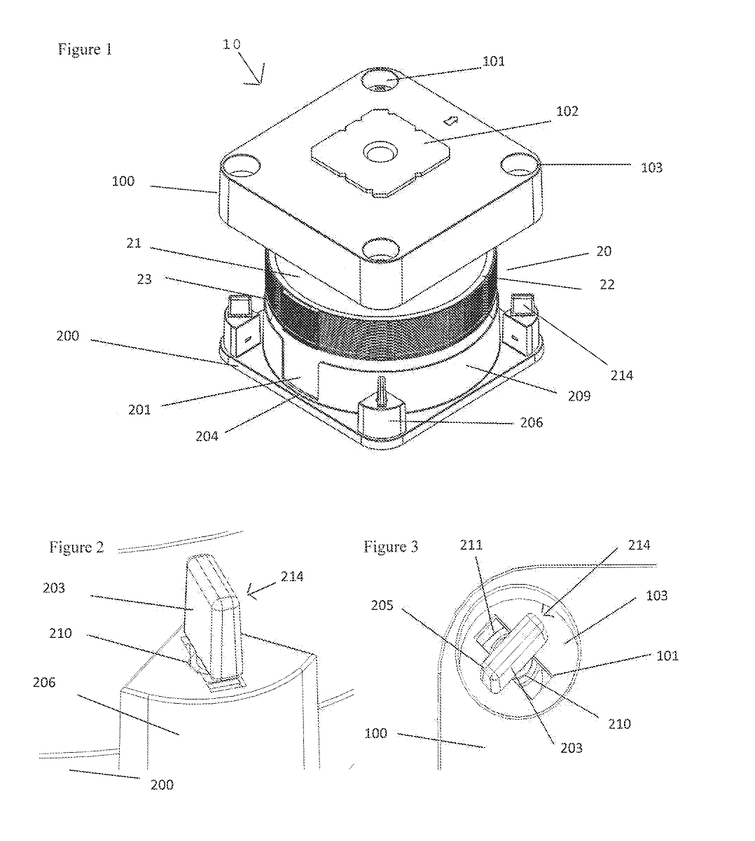

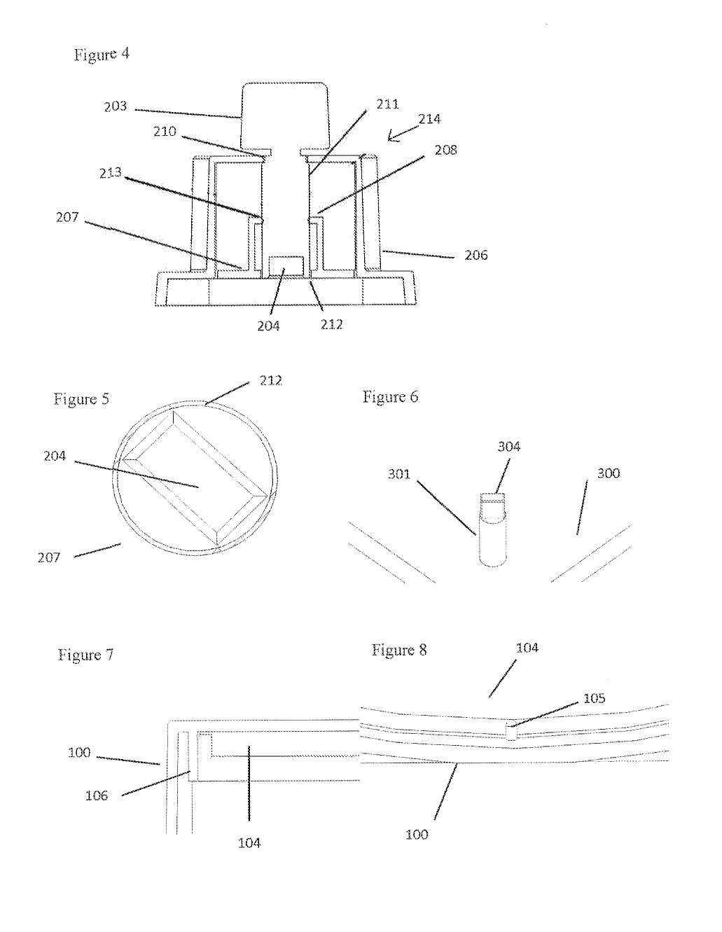

FIGS. 2, 3 and 4 show detailed views of the automated latch enclosure 206 with the automated latch tab 203 in the open position (see FIG. and closed position (see FIG. 3). FIG. 2 shows a perspective view of the automated latch enclosure 206 molded into the wafer carrier base 200 with the automated latch 214 positioned in the enclosure. The latch 214 includes a cylindrical body 211 with a reduced-diameter upper end 210 that is positioned and rotatable in a corresponding generally cylindrical hole in the top of the enclosure 206. FIG. 3 shows a perspective view of the automated latch 214 with the lid 100 in place and the latch tab 203 in a closed position. As the lid 100 is placed on the base 200 with the latch tab 203 in the open position, the latch tab 203 protrudes through the lid slot 101. To secure the lid 100 in place, the latch 214 is rotated 90 degrees to the closed position shown in FIG. 3. The latch 214 can be manually actuated by rotating the latch tab 203 in the lid latch recess 103.

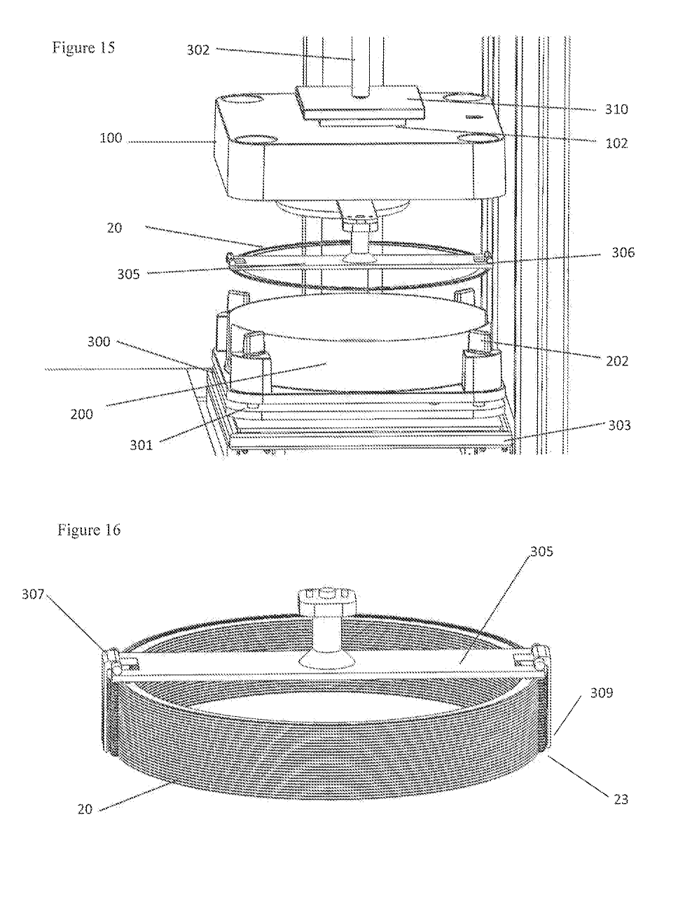

Referring to FIG, 4, the latch 214 is positioned in the latch enclosure 206 with the latch tab 203 protruding from the top of the enclosure 206. The enclosure 206 has generally cylindrical hole that accepts the latch body upper end 210 and which holds the latch body 211 in place laterally and allows it to rotate. Because the latch body 211 has a diameter that is larger than that of the latch body upper end, the latch 214 is secured from upward vertical movement. A latch retention clip 207 is pressed into the latch enclosure 206 to help secure the lower end of the latch body 211 in place and prevent its movement. The retention clip 207 includes locking centering arms 208 that press against the latch body 211. The latch body 211 also has flat surfaces 213 on opposing sides that are located so that the latch is secured in the closed position (see FIG. 3) when the arm terminations 208 are tangent to the flat surfaces 213. The retention clips 207 have a generally cylindrical hole planar to the bottom of a wafer carrier base 300 (see FIGS. 6 and 15), which hole accepts a latch body lower end 212. The latch body lower end 212 has a reduced diameter portion that closely fits into a hole in the wafer container base 200 (see FIG. 5). The latch 214 includes a keyed slot 204 that can connect to automated equipment actuators positioned below the wafer carrier base 200.

FIG. 5 shows a bottom view of the retention clip 207 hole planar to the wafer carrier base 200 with the latch body lower end 212 positioned in the cylindrical hole of the clip 207 and the keyed slot 204 that is access by automated equipment to open and close the latch 214 with a 90 degree rotary motion. FIG. 6 shows the wafer carrier base plate 300 with an actuator 301 and key 304 that mates with the wafer carrier keyed slot 204 to automatically open and close the wafer carrier latch 214.

Referring to FIGS. 7 and 8, a suspension component 104 can be mounted inside the top surface of the wafer container lid 100. A plurality of suspension component retention features 105 can be disbursed around the perimeter of the lid inner wall 106. The shape and location of the retention component are not critical provided they hold the suspension component in the lid during transportation and processing.

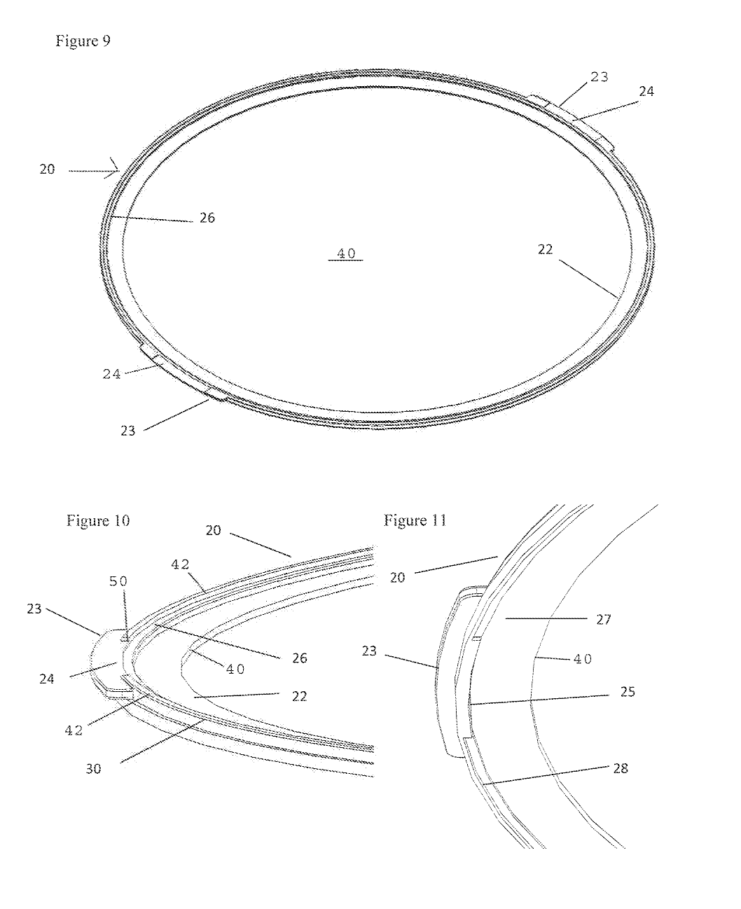

Referring to FIGS. 9-13, the wafer ring separator 20 has an outside diameter is larger than the diameter of a semiconductor wafer and a thickness that is thicker than the semiconductor wafer. A first top recessed portion or first top inner shoulder 26 is formed in the wafer separator 20 with a perimeter shape that corresponds to the shape of the semiconductor wafer. The ring separator 20 has two automation tabs 23 that protrude from the outside diameter and a second recessed portion 22 that forms a flat surface to allow the separator rings to be automatically handled.

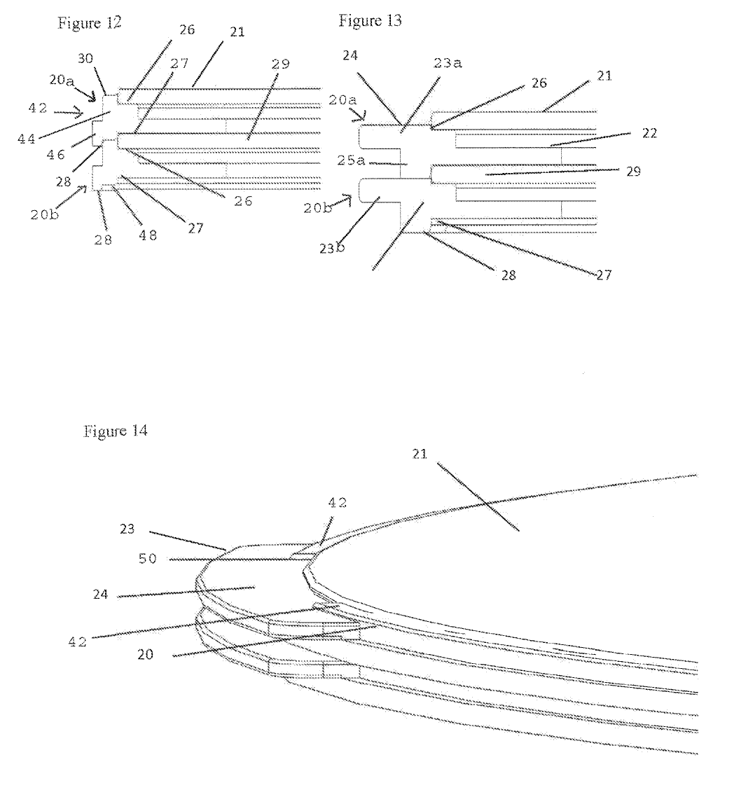

FIGS. 10, 11, and 13 show detailed perspective and section views of the ring separator 20 at the automation tab 23. FIG. 12 shows a section view of the perimeter details of the ring separator 20 at a central ring portion adjacent to the automation tab. The ring separator 20 has a maximum diameter that is greater than the wafer diameter. The ring separator 20 includes an outer rim 42 with an upper portion 44 having a top surface 30 and a lower portion 46 having bottom surface 28. The first top inner shoulder 26 is formed adjacent the rim upper portion 44 and has a perimeter shape that corresponds to the shape of the wafer 21 and is recessed from the rim top surface 30 by a depth that is less than the thickness of the wafer 21. A second recess portion or second top inner shoulder 22 is formed adjacent the first top inner shoulder 26 at a depth that is greater than the maximum height of the top side wafer topology (i.e., MEMS structures, solder bumps, contact pads, etc.) and provides a planar surface that can be accessed by vacuum robotic handling equipment. The second top inner shoulder 22 terminates at an opening 40 in the center of the ring. A first bottom recessed portion or first bottom inner shoulder 48 is formed adjacent the rim lower portion 46, and a second bottom recessed portion or second bottom inner shoulder 27 is formed adjacent the first bottom inner shoulder 48.

As shown in FIG. 12, the outer edge of the rim top surface 30 is sized and shaped to correspond with the inside perimeter of the bottom surface 28 so that when two of the separator rings 20a, 20b are stacked together the rim top surface 30 of the bottom ring 20b and the first bottom inner shoulder 48 of the top ring 20a form a continuous interlocking mate around the perimeter of two stacked wafer rings 20. The top outside and bottom inside interlocking surfaces can be chamfered with sufficient clearance to prevent sticking of two stacked rings 20a, 20b.

Referring to FIGS. 10, 11, 13 and 14, two opposing automation tabs 23 protrude outward from the perimeter of the ring outer rim 42 below the rim top surface 30. A recessed slot 50 is formed in the rim upper portion 44 adjacent the tab 23. The tab 23 has a generally planar top surface 24 that is co-planar with the bottom of the recessed slot 50 and is in a plane below the equator of a wafer pocket 29 formed by the first top inner shoulder 26 of the bottom stacked ring 20b and the second bottom inner shoulder 27 of the top stacked ring 20a. In this configuration, the recessed slot 50 forms an automation slot that allows automated vacuum wafer handling equipment to access the top surface of the wafer 21 even if the wafer's thickness is significantly reduced. The edge from the top surface to the automated tab can be chamfered or straight. The bottom ring surface 28 has an outside diameter than exceeds the outside diameter of the ring top surface 30. The first bottom inner shoulder 48 has an outer diameter that corresponds with the outer diameter of the rim top surface 30. The rim lower portion 44 also includes a downward projection 25 adjacent the automation tab 23 that corresponds with the recessed slot 50. The second bottom inner shoulder 27 is formed with a perimeter shape that corresponds to the shape of the wafer and is recessed from the first bottom inner shoulder 48 by a depth that is less than the thickness of the wafer 21. In this configuration, the wafer pocket 29 formed by the first top inner shoulder 26 of the bottom stacked ring 20b and the second bottom inner shoulder 27 of the top stacked ring 20a provides a continuous enclosure around the wafer perimeter and protection from wafer damage.

FIG. 14 shows a perspective view of a two ring 20 stack at the automation tab 23. The top surface of the wafer 21 is elevated above the ring top surface 30 and tab top surface 24 the bottom surface of the automation slot 50 are below the equator of the wafer allowing very thin wafers to be handled from the ring separator with vacuum pick up end effectors.

FIG. 15 shows an automated equipment interface for handling the wafer container of according to the present invention. A complete wafer container 10 is automatically placed on the wafer carrier mounting plate 300 with automatic sliding drawer 303 extended from the equipment workspace. The drawer 303 and wafer container 10 retract into the equipment workspace, and the actuators 301 in the carrier mounting plate 300 access the carrier base keyed automation slots 204 to open the automated latches 203. An automated lid removal tool 302 extends until a lid gripper 310 is positioned over the wafer container lid robotic flange 102. The lid gripper 310 secures the lid flange 102 and retracts to a position above the wafer container base 200. A ring separator robot secures a plurality of rings 20 from the wafer container base 200 using ring end effectors 305 with the latch arms extended (not shown). The latch arms of the ring end effectors 305 retract allowing the ring robot to individually transfer each ring separator 20 to the wafer container base 200. A wafer 21 is placed on the wafer ring separator 20 by a wafer robot (not shown) to the right of the wafer carrier base 200. When the wafer container base 200 is filled with a plurality of rings 20 and wafers 21, the lid 100 is replaced, the latches 203 are secured and the drawer 303 extends out of the equipment workspace to initiate a new process.

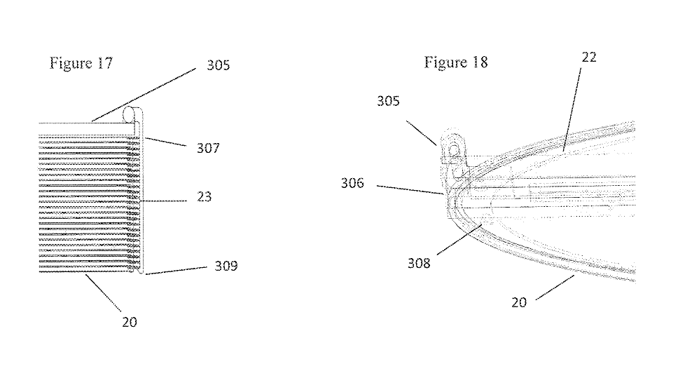

Referring to FIGS. 16 and 17, the ring end effectors 305 with extended pick up arms 307 securely hold a plurality of wafer rings 20 by the ring automation tabs 23 using tab gripper fingers 309. The distance between the extended pick up arms 307 corresponds to the distance across the ring automation tabs 23. An axle is firmly pressed into a hinge of the pick-up arm 307 and connects to an actuator, which controls the movement of the arms for opening, closing and gripping the ring automation tabs 23. In the extended position, the pick up arms 307 are perpendicular to the end effectors body 305. Narrow gripper fingers 309 are disposed at the tip of the arm 307, opposite the end effectors frame 305. The gripper fingers 309 correspond to the width of the automation tab 23 and are roughly with the end effectors body 305 and separator ring automation tabs 23. In this manner, the end effectors 305 and design of the interlocking separator rings 20 allow a plurality of wafers to be transferred effectively within the equipment workspace.

FIG. 18 shows a perspective view of the ring end effectors 305 with pick up arms 307 retracted within the end effectors frame. The end effectors 305 is holding a ring separator 20 using vacuum applied to a plurality of vacuum cups 308 disbursed uniformly around the end effectors frame 305 in positions that correspond with the flat vacuum pick up surface 22 of the ring separator 20.

Having read this disclosure, it will also be understood by those having skill in the art that modifications may be made to the invention without departing from its spirit and scope. Therefore, the invention in its broader aspects is not limited to the specific details, representative devices, and illustrative examples shown and described. Accordingly, departures may be made from such details without departing from the spirit or scope of the general inventive concept.

What is claimed is:

1. A wafer container for use with automated equipment, the container comprising:
a top lid adapted for engagement with a bottom base to form a housing having an inner cavity for storing at least one semiconductor wafer;
wherein the lid includes a handling member adapted to interface with automated equipment for placing the lid into engagement with the base and removing the lid from engagement with the base;
wherein the base includes a latch member and the lid includes a latch retainer portion adapted for receiving the latch member when the lid is in engagement with the base; and
wherein when the lid is in engagement with the base and the latch member is received by the lid latch retainer portion, the latch member can be actuated between a locked position and an unlocked position by automated equipment.

2. The wafer container of claim 1 wherein the latch member includes a tab adapted to protrude through a latch hole disposed in the lid when the lid is engagement with the base.

3. The wafer container of claim 2 wherein the tab can be rotated between the locked position and the unlocked position when it protrudes through the latch hole.

4. The wafer container of claim 1 wherein the tab is disposed within a recess in the lid when the tab is in engagement with the base and the tab protrudes through the latch hole.

5. The wafer container of claim 4 wherein the lid recess is sized to allow movement of the latch between the locked position and the unlocked position by hand.

6. The wafer container of claim 1 wherein the latch member includes a generally cylindrical body that is rotatable between the locked position and the unlocked position.

7. The wafer container of claim 5 further comprising a retainer clip adapted to removably secure the latch member to the base.

8. The wafer container of claim 1 wherein the housing inner cavity is adapted for holding a plurality of wafer separator rings in a stacked configuration.

9. The wafer container of claim 6 wherein each of the one or more wafer separator rings is adapted for placement on the base by automated equipment when the lid is not in engagement with the base.

10. The wafer container of claim 1 wherein the lid handling member comprises a flange adapted to interface with equipment for automatic removal and replacement of the lid.

11. The wafer container of claim 6 wherein the base includes a latch enclosure and the latch member cylindrical body is disposed within the latch enclosure with a bottom portion of the cylindrical body is accessible at the bottom of the base to automation equipment for rotating the latch between the closed position and the open position.

12. The wafer container of claim 1 wherein at least one wafer suspension component is removably secured to the inside top of the lid.

13. A wafer container for use with automated equipment, the container comprising:
a top lid adapted for engagement with a bottom base to form a housing having an inner cavity for storing at least one semiconductor wafer having a diameter; and
at least two wafer separator rings disposed inside the inner cavity;
wherein each of the separator rings includes an outer rim having an outer diameter that is larger than the semiconductor wafer diameter and at least one automation tab extending outwardly from the outer rim.

14. The wafer container of claim 13 wherein the at least two of the wafer separator rings are configured so that when they are disposed inside the inner cavity in a stacked arrangement they define a pocket between the wafer separator rings for closely holding a peripheral portion of the semiconductor wafer.

15. The wafer separator ring of claim 14 wherein the stacked wafer separator rings have interlocking mating surfaces that are chamfered.

16. The wafer container of claim 13 wherein the wafer separator ring automation tab defines a generally planar top surface that is offset below a top surface of the outer rim.

17. The wafer container of claim 13 wherein the outer rim includes a recessed slot adjacent the automation tab top surface.

18. The wafer container of claim 116 wherein the depth of the outer rim recessed slot is below the equator of a semiconductor wafer positioned in the wafer separator ring.

19. The wafer container of claim 16 wherein the outer rim includes a projection opposing the recessed slot and that has dimensions that corresponds with the depth and width of the recessed slot.

20. A wafer separator ring for use with a container for semiconductor wafers, the wafer separator ring comprising:
an outer rim including:
an upper portion having a generally planar top surface and an outer diameter that is greater than the diameter of a semiconductor wafer, and
and an opposing tower portion having a bottom surface and an outer diameter that is greater than the top portion outer diameter;
a first top inner shoulder disposed inward of the rim upper portion and recessed from the rim top surface, wherein the first top inner shoulder has an outer diameter that is slightly larger than the wafer diameter and has a perimeter shape that corresponds to the shape of the wafer perimeter;
a second top inner shoulder disposed inward of and recessed from the first top inner shoulder;
a first bottom inner shoulder disposed inward of the rim lower portion and recessed from the rim bottom surface, wherein the first bottom inner shoulder has an outer diameter that is slightly larger than the rim upper portion outer diameter; and
a second bottom inner shoulder disposed inward of and recessed from the first bottom inward shoulder, wherein the second bottom inner shoulder has a diameter that is slightly larger than the wafer diameter;
wherein rim the lower portion has in inner diameter at the first bottom inner shoulder that corresponds to the perimeter

21. The wafer separator ring of claim 20 wherein:
the first top inner shoulder has a recess depth that is greater than half the thickness of the peripheral portion of the wafer;
the second bottom inner shoulder has a recess depth that is less than half the thickness of the peripheral portion of the wafer; and
the sum of the first top inner shoulder recess depth and the second bottom inner shoulder recess depth is greater than the thickness of the peripheral portion of the wafer. The wafer separator ring of claim 20 wherein the second top recessed inner shoulder defines a generally planar vacuum pickup surface having sufficient width for engaging a vacuum cup of automated handling equipment.
